(19) United States
(12) Patent Application Publication
(10) Pub. No.: US 2018/0241168 A1
(43) Pub. Date: Aug. 23, 2018

(54) System For Determining Mounting State of Pins of Electrical Connector

(71) Applicants: Tyco Electronics (Shanghai) Co. Ltd., Shanghai (CN); TE Connectivity Corporation, Bewyn, PA (US)

(72) Inventors: Lei Zhou, Shanghai (CN); Dandan Zhang, Shanghai (CN); Lvhai Hu, Shanghai (CN); Zhiyong Dai, Shanghai (CN); Roberto Francisco-Yi Lu, Berwyn, PA (US)

(73) Assignees: Tyco Electronics (Shanghai) Co. Ltd., Shanghai (CN); TE Connectivity Corporation, Berwyn, PA (US)

(21) Appl. No.: 15/958,103

(22) Filed: Apr. 20, 2018

Related U.S. Application Data
(63) Continuation of application No. PCT/IB2016/056170, filed on Oct. 14, 2016.

(30) Foreign Application Priority Data
Oct. 20, 2015 (CN) 201510683384.6

(51) Int. Cl. H01R 43/20; G01R 31/304; H05K 13/08; G01B 11/26

(52) U.S. Cl. CPC H01R 43/205; G01B 11/26; H05K 13/08; G01R 31/304

(57) ABSTRACT

A system for determining a mounting state of a plurality of pins protruding from a mounting surface of an insulating housing of an electrical connector comprises an image capturing device and an identifying device. The image capturing device is adapted to capture an image of a detected pin of the plurality of pins of the electrical connector. The image capturing device captures the image in a capturing direction which is at an acute angle with respect to an extending direction of an ideal pin protruding perpendicularly from the mounting surface. The identifying device is adapted to identify whether or not the detected pin in the image is within a predetermined region of the image. The identifying device determines the mounting state of the detected pin as unqualified when the detected pin in the captured image extends beyond the predetermined region.

### CROSS-REFERENCE TO RELATED APPLICATIONS

This application is a continuation of PCT International Application No. PCT/IB2016/056170, filed on Oct. 14, 2016, which claims priority under 35 U.S.C. § 119 to Chinese Patent Application No. 201510683384.6, filed on Oct. 20, 2015.

### FIELD OF THE INVENTION

The present invention relates to a system for determining a mounting state of pins of an electrical connector and, more particularly, to a system for determining the mounting state of pins of the electrical connector using an image capturing device.

### BACKGROUND

An electrical connector generally includes an insulating housing and a plurality of connecting terminals mounted in the insulating housing. In some electrical connectors, several terminals extend from the insulating housing to form pins electrically or mechanically connected to an electronic device, such as a Printed Circuit Board (PCB), or connected to other electrical connectors. The pins are arranged in a predetermined manner and the electronic device has insertion holes corresponding to these pins.

To ensure each pin of the electrical connector is smoothly inserted into a corresponding insertion hole, each pin must be maintained in a predetermined orientation extending out of the insulating housing, such as perpendicular to a surface of the insulating housing. It is thus necessary to detect a mounting state of pins on the electrical connector in the process of manufacturing the electrical connector. If the mounting state of any of the pins on the electrical connector is detected as not meeting predetermined requirements, the electrical connector is disqualified.

### SUMMARY

A system for determining a mounting state of a plurality of pins protruding from a mounting surface of an insulating housing of an electrical connector comprises an image capturing device and an identifying device. The image capturing device is adapted to capture an image of a detected pin of the plurality of pins of the electrical connector. The image capturing device captures the image in a capturing direction which is at an acute angle with respect to an extending direction of an ideal pin protruding perpendicularly from the mounting surface. The identifying device is adapted to identify whether or not the detected pin in the image is within a predetermined region of the image. The identifying device determines the mounting state of the detected pin as unqualified when the detected pin in the captured image extends beyond the predetermined region.

### BRIEF DESCRIPTION OF THE DRAWINGS

The invention will now be described by way of example with reference to the accompanying Figures, of which:

FIG. 1 is a perspective view of a system for determining a mounting state of a plurality of pins of an electrical connector according to an embodiment;

FIG. 2 is a schematic diagram of an image capturing device, an identifying device, and the pins of the system of FIG. 1;

FIG. 3 is a side view of an ideal mounting state of the pins on an insulating housing of the electrical connector;

FIG. 4 is a schematic diagram of an image of the pins of FIG. 3 obtained by the system of FIG. 1;

FIG. 5 is a schematic diagram of the image capturing device along with an ideal pin and a detected pin of the pins;

FIG. 6 is a schematic diagram of a geometric relationship between the ideal pin and the detected pin of FIG. 5;

FIG. 7 is a side view of a mounting state of a plurality of pins on the insulating housing;

FIG. 8 is a schematic diagram of an image of the pins of FIG. 7 obtained by the system of FIG. 1;

FIG. 9 is a perspective view of a system for determining a mounting state of a plurality of pins of an electrical connector according to another embodiment;

FIG. 10 is a schematic diagram of an image capturing device, an identifying device, and the pins of the system of FIG. 9;

FIG. 11 is a schematic diagram of the image capturing device along with an ideal pin and a detected pin of the pins;

FIG. 12 is a schematic diagram of a geometric relationship between the ideal pin and the detected pin of FIG. 11;

FIG. 13 is a schematic diagram of an image of the pins of FIG. 10 obtained by the system of FIG. 9;

FIG. 14 is a schematic diagram of an image of the pins of FIG. 3 obtained by the system of FIG. 9; and

FIG. 15 is a schematic diagram of an image of the pins of FIG. 7 obtained by the system of FIG. 9.

### DETAILED DESCRIPTION OF THE EMBODIMENT(S)

Exemplary embodiments of the present invention will be described hereinafter in detail with reference to the attached drawings, wherein like reference numerals refer to like elements. The present invention may, however, be embodied in many different forms and should not be construed as being limited to the embodiments set forth herein. Rather, these embodiments are provided so that the present disclosure will be thorough and complete and will fully convey the concept of the disclosure to those skilled in the art.

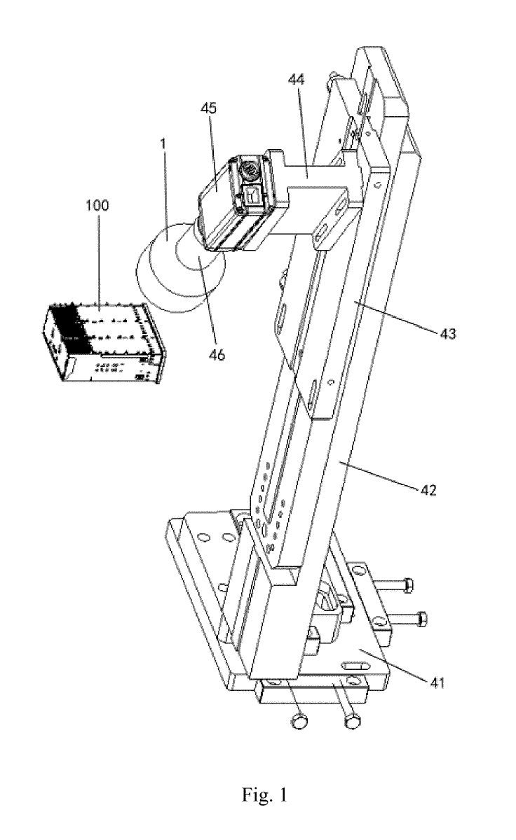

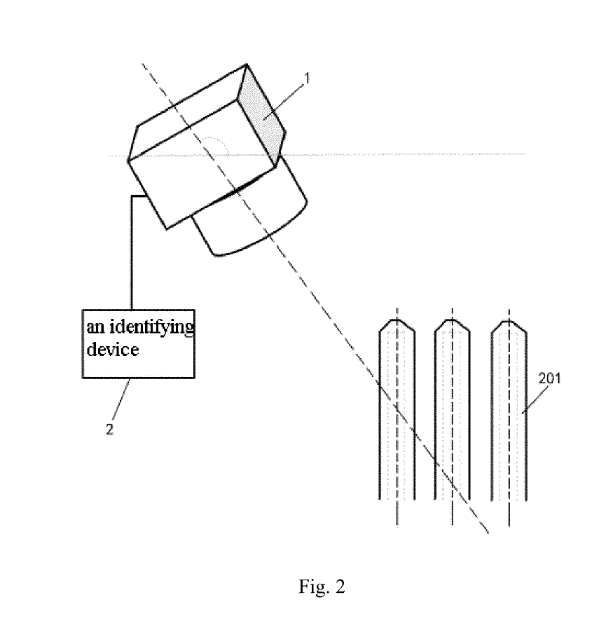

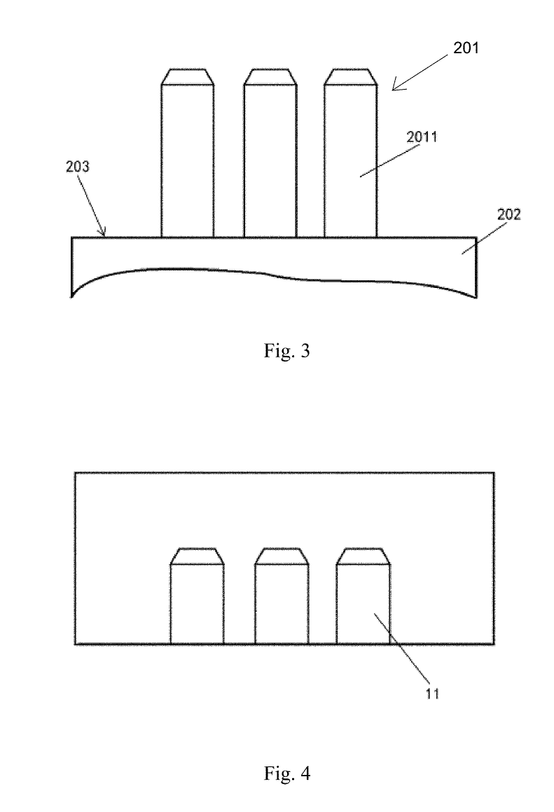

A system for determining a mounting state of a plurality of pins 201 of an electrical connector 100 is shown in FIGS. 1 and 2. The pins 201, as shown in FIG. 3, protrude from a mounting surface 203 of an insulating housing 202 of the electrical connector 100. The pins 201 are adapted to be electrically or mechanically connected to, for example, a Printed Circuit Boards (PCB) or other electrical connectors in a plug-in manner to transmit electrical signals therebetween.

An ideal mounting state of the pins 201 is shown in FIG. 3; the pins 201 extend out of the insulating housing 202 in a direction perpendicular to the mounting surface 203 of the insulating housing 202. However, due to limits of operating conditions, the pins 201 may actually be arranged as shown in FIG. 7, that is, some pins 201 extend out of mounting surface 203 of the insulating housing 202 in an inclined manner. In order to smoothly insert the pins 201 into the printed circuit board, it is desirable to maintain the inclined angles of the pins 201 within a predetermined range, for example, not to exceed 20 degrees. Otherwise, it is possible to curve the pins 201 and/or damage the circuit board during insertion of the pins 201 into the circuit board, causing products to be unqualified.

As shown in FIGS. 1, 2, 4, 7 and 8, the system for determining the mounting state of the pins 201 of the electrical connector 100 comprises a positioning device adapted to position the electrical connector 100, an image capturing device 1 adapted to capture an image 11 of the pins 201 of the electrical connector 100, and an identifying device 2. In an embodiment, the image capturing device 1 is a camera. In various embodiment, the positioning device may be a conveyor belt, a manipulator, or any other device capable of positioning the electrical connector 100.

The identifying device 2 includes a processor and a memory. The memory is a non-transitory medium having an algorithm stored thereon that is executable by the processor. The identifying device 2, by executing the algorithm via the processor, compares the pins 201 in the captured image 11 with a predetermined region 3 of the image pre-stored in the memory of the identifying device 2. The identifying device 2 is adapted to identify whether or not the pins 201 in the captured image 11 are within the predetermined region 3.

The identifying device 2 determines a mounting state of the pin 201 to be unqualified when identifying that the captured image 11 of the pins 201 extends beyond the predetermined region 3. A position and a gesture of the image capturing device 1 is predetermined relative to the electrical connector 100; that is, images of identical electrical connectors 100 captured in the image capturing device 1 have identical sizes, shapes and positions. The system identifies the mounting state accurately and quickly and determines whether or not the mounting state of the pins 201 is qualified online and in real-time, reducing manual labor for identifying the qualifying state of the pins 201.

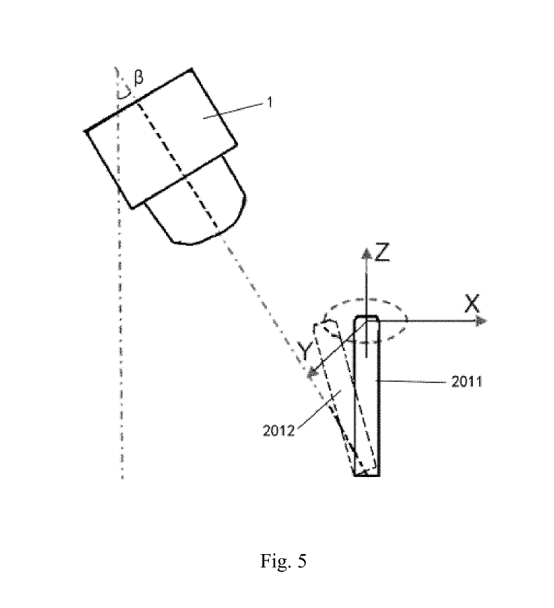

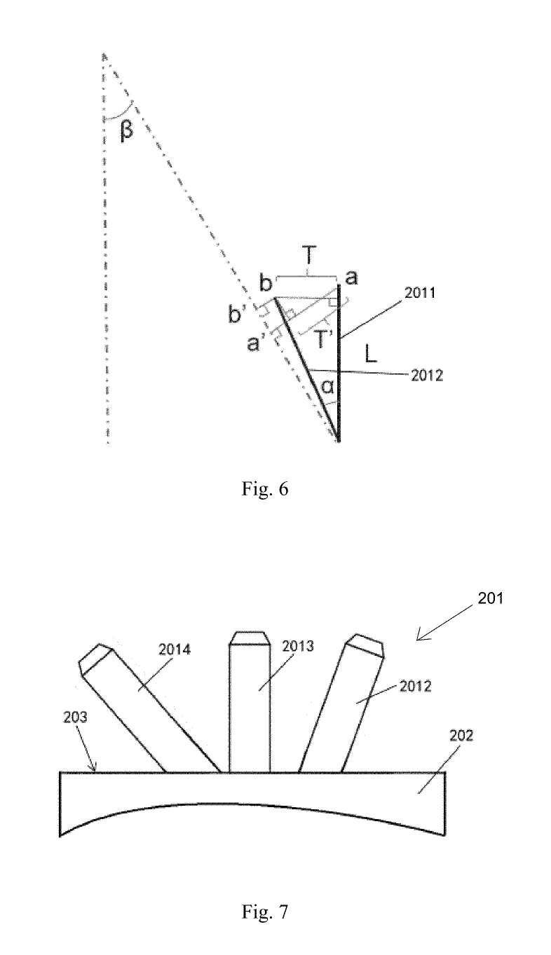

As shown in FIGS. 5 and 6, the image capturing device 1 is positioned to capture an image of an detected pin 2012 extending in a direction which is at an acute angle β with respect to an extending direction of an ideal pin 2011. The ideal pin 2011 extends a length L out of the mounting surface 203 of the insulating housing 202. The detected pin 2012 to be detected is inclined with respect to the ideal pin 2011 and also extends the length L out of the mounting surface 203.

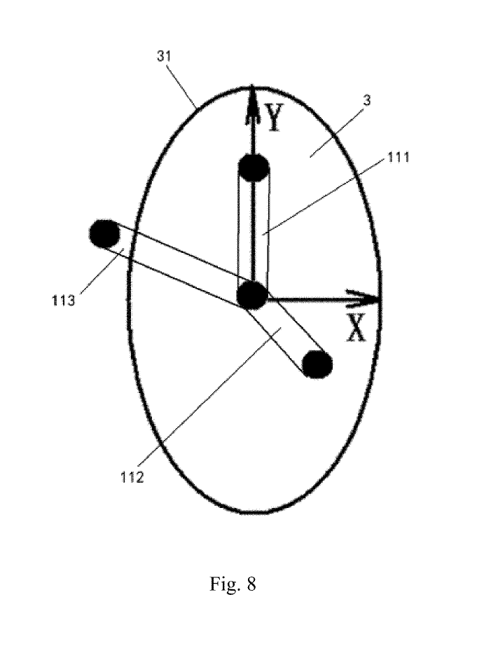

In an embodiment, the predetermined region 3 comprises a planar region defined by an ellipse 31 shown in FIG. 8. The ellipse 31 satisfies an equation below in a rectangular coordinate system:

$$\frac{{x}^{2}}{{( {T}^{′} )}^{2}} + \frac{{y}^{2}}{{T}^{2}} = 1 , \qquad ( Eqn . 1 )$$

wherein T=C*L*sin α, and T′=C*L*sin β−C*L*sin (β−α)

The angle α, shown in FIG. 6, is the largest allowable inclined angle of the detected pin 2012 with respect to the ideal pin 2011. β is an angle between the capturing direction of the image capturing device 1 and a direction in which the ideal pin 2011 extends, and C is a magnification of the image 11 captured by the image capturing device 1 relative to the detected pin 2012.

As shown in FIG. 5, in a three-dimensional coordinate system defined by X, Y, and Z axes, the ideal pin 2011 is located at the Z-axis, the angled pin 2012 with the largest allowable inclined angle α is inclined relative to the Z-axis only in the Y-axis but not in the X-axis, the lengths by which the ideal pin 2011 and the detected pin 2012 extend out of the mounting surface are both L, and in a plane defined by the Y and Z axes, an angle between the capturing direction of the image capturing device 1 and a direction in which the ideal pin 2011 extends is β.

A distance T between an end a of the ideal pin 2011 and an end b of the detected pin 2012 shown in FIG. 6 is:

T=L*sin α (Eqn. 2)

A difference T′ between a distance between the end a of the ideal pin 2011 and a central axis of the image capturing device 1 and a distance between the end b of the detected pin 2012 and the central axis of the image capturing device 1 is:

T′=distance(a,a′)−distance(b,b′)=L*sin β−L*sin(β−α) (Eqn. 3)

Further considering the magnification C of the image captured by the image capturing device 1 relative to the detected pin 2012, the above Equation 1 for the ellipse 31 is obtained.

Three types of detected pins 2012, 2013 and 2014 extending out of the mounting surface 203 of the insulating housing 202 are shown in FIG. 7. Images of the three detected pins 2012, 2013 and 2014 captured in the image capturing device 1 are shown in FIG. 8; the detected pin 2013 has an image 111, the detected pin 2012 has an image 112, and the detected pin 2014 has an image 113. The identifying device 2 determines that the respective captured images 112 and 111 of the detected pins 2012 and 2013 are within the predetermined region 3 defined by the ellipse 31, and the mounting state of the detected pins 2012 and 2013 is thus qualified. The image 113 of the detected pin 2014 extends beyond the predetermined region 3 defined by the ellipse 31, indicating that the inclined angle of the detected pin 2014 extends beyond an allowable limit and the mounting state of the detected pin 2014 is unqualified.

The image capturing device 1 is positioned to capture the image 11 of the detected pin 2012 in the direction which is at the acute angle β with respect to the extending direction of the ideal pin 2011. The area of the captured image 11 is thereby increased, including an image of a rod portion and an end of the detected pin 2012, which improves identification precision and accuracy, avoiding misjudgment. In the case where the magnification C of the image captured by the image capturing device 1 relative to the detected pin 2012 is constant, the distance between the electrical connector 100 and the image capturing device 1 does not need to be considered and there is no special limit to a light source for image capturing, improving flexibility and reducing cost of the detection. In an embodiment, the largest allowable inclined angle α of a detected pin 2012 with respect to the ideal pin 2011 is larger than the angle β between the capturing direction of the image capturing device 1 and a direction in which the ideal pin 2011 extends, ensuring that images of qualified pins fall within the predetermined region 3 to facilitate identification of unqualified pins.

The system for determining the mounting state of the pins 201 of the electrical connector 100, as shown in FIG. 1, further comprises a carrying device adapted to hold and move the image capturing device 1, adapted to adjust the distance between the image capturing device 1 and the electrical connector 100, and adapted to adjust the orientation of the image capturing device 1 relative to the electrical connector 100. The carrying device allows, in a plane defined by the Y and Z axes, the capturing direction of the image capturing device 1 to be set at an angle β with respect to a direction in which the ideal pin 2011 extends.

As shown in FIG. 1, the carrying device comprises a base 41 mounted on a mounting frame, a rail mechanism 42 vertically mounted on the base 41, a sliding mechanism 43 slidably mounted on the rail mechanism 42 in the vertical direction, a rotating arm 44 mounted on the sliding mechanism 43 and rotatable relative to the rail mechanism 42, an inclined arm 45 mounted on the rotating arm 44 to rotate relative to the rail mechanism 42, and a telescopic arm 46 mounted on the inclined arm 45 and retractable relative to the inclined arm 45. The image capturing device 1 is mounted on the telescopic arm 45. When the electrical connector 100 is positioned, the distance between the image capturing device 1 and the electrical connector 100 and the orientation of the image capturing device 1 relative to the electrical connector 100 may be adjusted by at least one of sliding, rotating, inclining, and retracting the image capturing device 1 using the carrying device. In an embodiment, the carrying device may further comprise at least one driving device, such as servo motor, to drive the motion operations of sliding, rotating, inclining, retracting, etc. The carrying device holds the image capturing device 1 at a predetermined distance and orientation relative to the electrical connector 100 for capturing of the image 11.

In an embodiment, the system for determining the mounting state of the pins 201 further comprises a grasping device adapted to move a detected electrical connector 100 to an apparatus for storing unqualified products when the mounting state of the pins 201 is determined as unqualified. In an embodiment, the grasping device is a robotic arm.

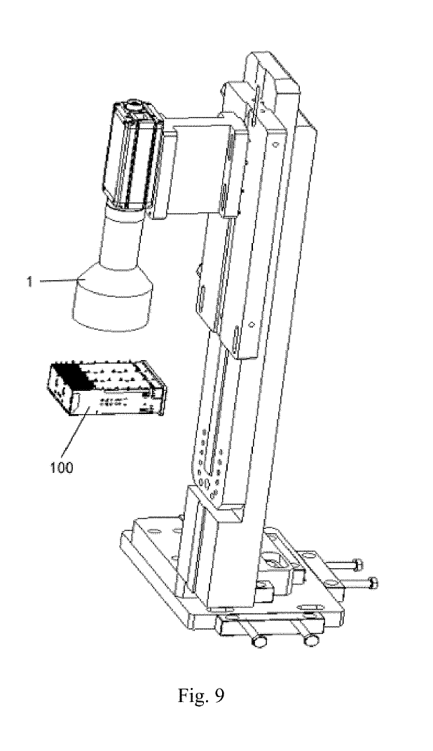

Another embodiment of a system for determining the mounting state of pins 201 of the electrical connector 100 is shown in FIG. 9. Like reference numbers indicate like elements with respect to the embodiment shown in FIGS. 1-8 and only the differences with respect to the embodiment of FIGS. 1-8 will be described in detail herein.

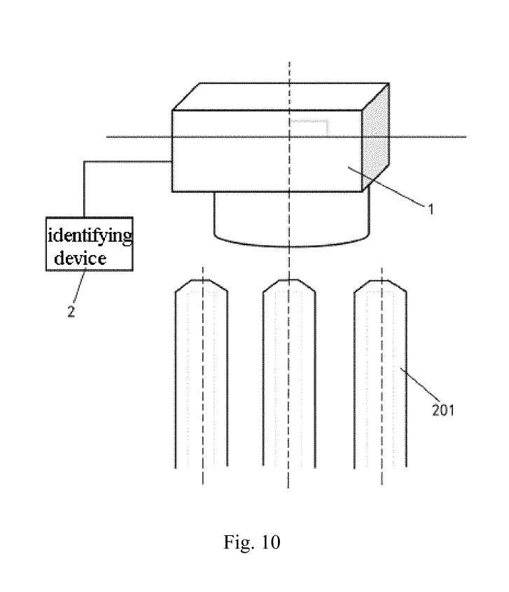

The system shown in FIGS. 9-11 differs from that shown in FIG. 1 in that the image capturing device 1 shown in FIGS. 9-11 is positioned to capture images of the pins 201 in a direction in which an ideal pin 2011 extends. The ideal pin 2011 extends out of the mounting surface 203 perpendicularly and at a length L.

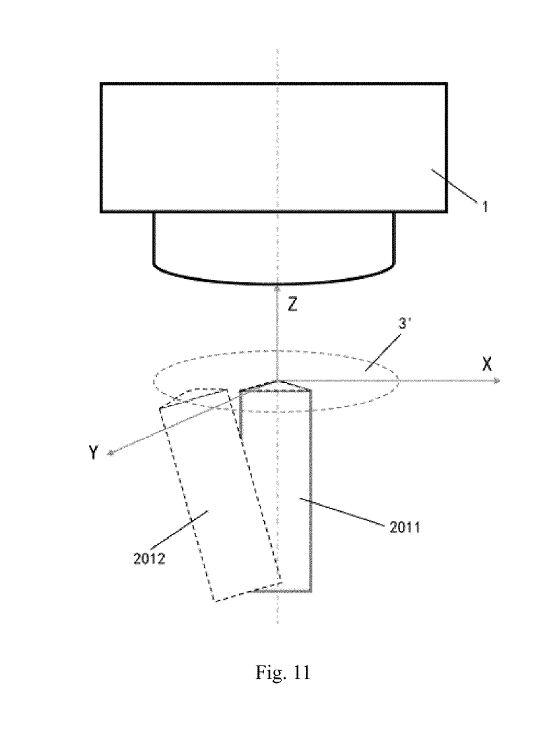

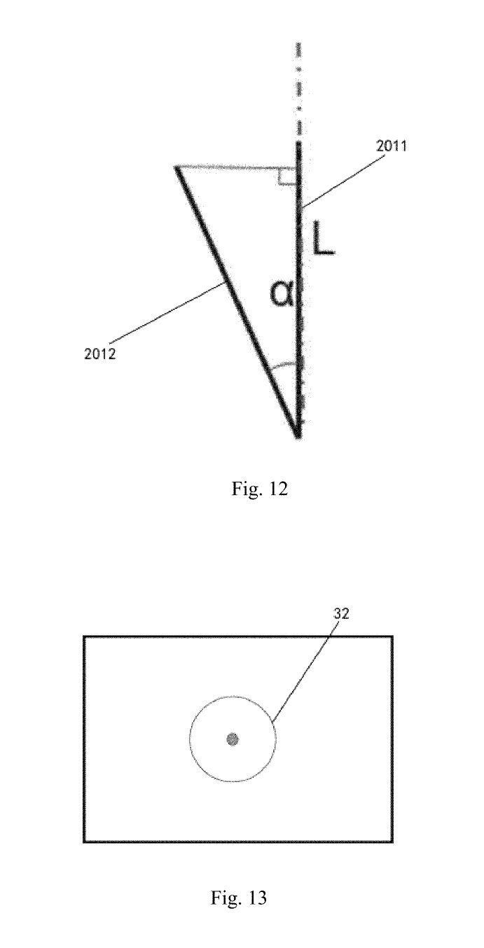

As shown in FIGS. 11-13, the predetermined region 3′ comprises a planar region defined by a circle 32 which satisfies an equation below in a rectangular coordinate system:

X2+Y2=(C*L*sin α)2, (Eqn. 4)

wherein α is the largest allowable inclined angle of the detected pin 2012 with respect to the ideal pin 2011, and C is a magnification of the image captured by the image capturing device 1 relative to a detected pin 2012.

In this case, if the identifying device 2 identifies that the image 11 of the detected pin 2012 is within the predetermined region 3′, then the mounting state of the detected pin 2012 is determined to be qualified. If the image 11 of the detected pin 2012 extends beyond the predetermined region 3′ defined by the circle 32, the inclined angle of the detected pin 2012 exceeds an allowable limit and the mounting state of the detected pin 2012 is unqualified.

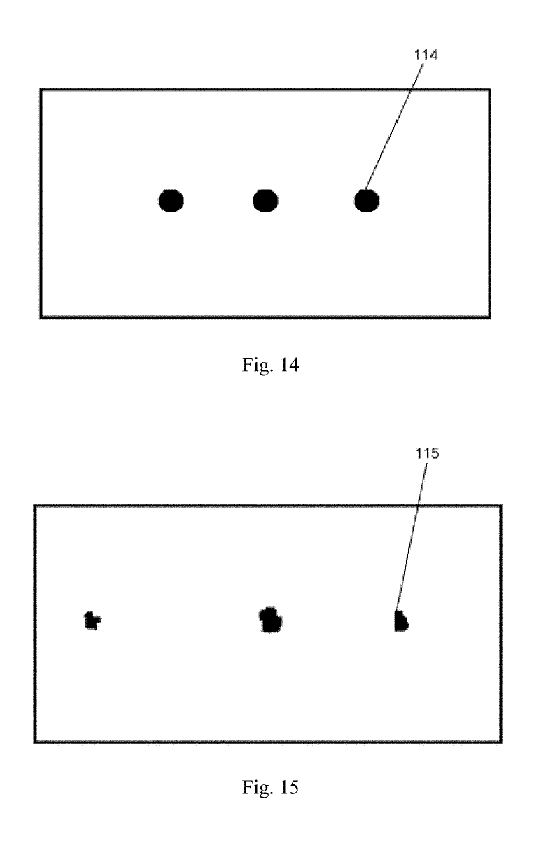

In the system according to the embodiment shown in FIG. 9, since the image capturing device 1 is positioned to capture images of the detected pins 2012 in a direction in which the ideal pin 201 extends, the obtained image 11 mainly comprises images of ends of the detected pins 2012, causing an area of the obtained image 11 to be smaller. A captured image 114 of the detected pin 2012 in which the detected pin 2012 is generally perpendicular to the mounting surface 203, such as the pins 201 shown in FIG. 3, is shown in FIG. 14 and a captured image 115 showing the detected pin 2012 with an inclined angle with respect to the mounting surface 203, such as the pins 201 shown in FIG. 7, is shown in FIG. 15.

What is claimed is:

1. A system for determining a mounting state of a plurality of pins protruding from a mounting surface of an insulating housing of an electrical connector, comprising:
an image capturing device adapted to capture an image of a detected pin of the plurality of pins of the electrical connector, the image capturing device capturing the image in a capturing direction which is at an acute angle with respect to an extending direction of an ideal pin protruding perpendicularly from the mounting surface; and
an identifying device adapted to identify whether or not the detected pin in the image is within a predetermined region of the image, the identifying device determining the mounting state of the detected pin as unqualified when the detected pin in the captured image extends beyond the predetermined region.

2. The system of claim 1, further comprising a positioning device adapted to position the electrical connector.

3. The system of claim 2, wherein the positioning device is a conveyer belt or a manipulator.

4. The system of claim 1, wherein the predetermined region is a planar region defined by an ellipse.

5. The system of claim 4, wherein, in a rectangular coordinate system, the ellipse of the predetermined region satisfies an equation:
$$\frac{{x}^{2}}{{( {T}^{′} )}^{2}} + \frac{{y}^{2}}{{T}^{2}} = 1 ,$$
wherein T=C*L*sin α, and T′=C*L*sin β−C*L*sin (β−α), L is a length by which the ideal pin protrudes from the mounting surface, α is a largest allowable inclined angle of the detected pin with respect to the ideal pin, β is an angle between the capturing direction of the image capturing device and the extending direction of the ideal pin, and C is a magnification of the image captured by the image capturing device relative to the detected pin.

6. The system of claim 5, wherein the largest allowable inclined angle of the detected pin with respect to the ideal pin is less than the angle of the capturing direction of the image capturing device with respect to the extending direction of the ideal pin.

7. The system of claim 1, further comprising a carrying device adapted to hold and move the image capturing device.

8. The system of claim 7, wherein the carrying device is adapted to adjust a distance between the image capturing device and the electrical connector.

9. The system of claim 8, wherein the carrying device is adapted to adjust an orientation of the image capturing device relative to the electrical connector.

10. The system of claim 9, wherein the carrying device holds the image capturing device at a predetermined distance and orientation relative to the electrical connector for capturing of the image.

11. The system of claim 9, wherein the carrying device includes:
a base mounted on a mounting frame;
a rail mechanism vertically mounted on the base;
a sliding mechanism slidably mounted on the rail mechanism;
a rotating arm mounted on the sliding mechanism and rotatable relative to the rail mechanism;
an inclined arm mounted on the rotating arm and rotatable relative to the rail mechanism; and
a telescopic arm mounted on the inclined arm and retractable relative to the inclined arm.

12. The system of claim 11, wherein the image capturing device is mounted on the telescopic arm.

13. The system of claim 1, further comprising a grasping device adapted to move the electrical connector to an apparatus for storing unqualified products when the mounting state of the detected pin is determined as unqualified.

14. The system of claim 1, wherein the predetermined region is pre-stored in the identifying device.
